(19) United States
(12) Patent Application Publication
(10) Pub. No.: US 2021/0181042 A1
(43) Pub. Date: Jun. 17, 2021

(54) BENDING SENSING DEVICE

(71) Applicant: National Chiao Tung University, Hsinchu (TW)

(72) Inventors: Ying-Hao Chu, Hsinchu County (TW); Min Yen, Kaohsiung (TW)

(21) Appl. No.: 16/920,464

(22) Filed: Jul. 3, 2020

(30) Foreign Application Priority Data
Dec. 11, 2019 (TW) 108145390

(51) Int. Cl. G01L 1/18; H01L 29/84

(52) U.S. Cl. CPC G01L 1/18; H01L 29/84

(57) ABSTRACT

A bending sensing device comprises a substrate, a piezoresistive thin film and at least a pair of electrodes. The substrate is flexible and having a two-dimensional structure, and a material of the substrate is mica. The piezoresistive thin film is disposed on the substrate whose material is inorganic compound comprising zinc oxide (ZnO), doped ZnO, germanium (Ge), doped Ge, or any combinations thereof. The at least a pair of electrodes are disposed separately on two terminals of at least a measurement section of the piezoresistive thin film to electrically connect the measurement section.

### CROSS-REFERENCE TO RELATED APPLICATION

This application claims the benefit of Taiwan Patent Application No. 108145390, filed on Dec. 11, 2019, in the Taiwan Intellectual Property Office, the disclosure of which is entirely incorporated herein by reference.

### FIELD OF TECHNOLOGY

This invention is related to a bending sensing device, particularly an electronic device that can be bent in multiple segments and sensing these multiple segments simultaneously.

### BACKGROUND

In the past few years, various types of sensors have developed rapidly and their application fields are quite wide. The inventions of these sensors are mostly designed to mimic biological behavior and sense biological perception to achieve mechanical biomimetic purposes, including the senses of touching, tasting, smelling, motion analysis, etc., and even detection that cannot be sensed by humans, such as electromagnetic waves, infrared, etc.

Bending is involved in the movement of each joint. As far as the current sensors for controlling the mechanical bending action are concerned, most of the sensors receive active instructions and then move without reverse detection, or utilize pressure, optics, etc. to laterally detect the bending action and then analyze and calculate the bending action. The above detection ways of the sensors are all indirect, and a large amount of data collection is required. These data needs to be further calculated and analyzed to sense a simple bending action. Unfortunately, commercially available varieties of the control sensors are still relatively rare and only supporting for simple functions, and they are mostly based on organic materials. Taking organic materials as the main part, it has the advantages of good mechanical properties and lower cost. But generally speaking, the existing products have drawbacks of poor accuracy, poor sensitivity, poor durability (not resistant to high temperature and acid/alkali or cannot be reused), dark or opaque appearance (not suitable for anthropomorphic limbs and transparent technology), bulky, difficult to be integrated with other sensors or small electronic devices, and single sensing direction. Therefore, the various application limitations of organic materials in the field of sensors have become urgent problems to be solved in this field, and thus researchers have also put more effort into other more prospective sensing device materials.

### SUMMARY

In order to solve the above problems, a bending sensing device mainly comprising an inorganic and a piezoresistive material is provided. Because piezoresistive material has detection convenience and bendability, after the bending sensing device is further combined with inorganic materials, it has the advantages of lightness, transparency, flexibility, high temperature and acid resistance, long product life cycle, etc. What is more, it can take advantage of the high temperature resistance of this sensing device to directly combine it with other sensors or electronic components in a process, and a new multifunctional component can be obtained. In addition to reducing the efficiency loss caused by assembly, it can also significantly reduce the volume of the final product, which is extremely important for industries that require miniaturization.

Even unexpectedly, due to the high sensitivity of the bending sensing device, its bending measurement can be performed at the same time in multiple sections (that is, multiple points) and multiple axes, overcoming the measurement of the whole bending sensing device in the past which leads to the shortcomings of simply detecting on a single bending section at the same time. The bending sensing device can also be miniaturized due to its high sensitivity, without losing its performance, breaking through the dilemma of volume limitation of the existing bending sensing device due to the low unit area sensing efficiency.

According to an embodiment of this invention, a bending sensing device is provided. The bending sensing device comprises a substrate, a piezoresistive thin film and at least one pair of electrodes. The substrate having a flexible two-dimensional structure, wherein a material of the substrate is mica. The piezoresistive thin film disposed on the substrate and having at least one measurement section, wherein a material of the piezoresistive thin film is an inorganic material comprising zinc oxide, doped zinc oxide, germanium, doped germanium, or any combinations thereof. The at least one pair of electrodes respectively disposed on two terminals of the at least one measurement section of the piezoresistive thin film.

According to another embodiment, these electrodes are made from a transparent conductive oxide comprising indium tin oxide or doped zinc oxide.

According to another embodiment, the bending sensing device further comprises a plurality of protection layers covering exposed surfaces of the substrate, the piezoresistive thin film and the electrodes, wherein a material of these protection layers comprises polyethylene terephthalate (PET).

According to another embodiment, the at least one measurement section is disposed on at least one axial direction of the bending sensing device.

According to another embodiment, the at least one measurement section is curved and has a curvature radius not less than 3.5 mm.

According to another embodiment, the bending sensing device further comprises a plurality of resistance measurement devices respectively electrically connected to the electrodes to measure a plurality of resistance values.

According to another embodiment, the substrate has a thickness of not greater than 100 μm.

According to another embodiment, the piezoresistive thin film has a thickness of 100-10000 nm.

According to another embodiment, the piezoresistive thin film is disposed on the substrate in such a manner that the direction of the Miller index [001] of the piezoresistive thin film is perpendicular to the substrate when the piezoresistive thin film is zinc oxide or doped zinc oxide.

According to another embodiment, the piezoresistive thin film is disposed on the substrate in such a manner that the direction of the Miller index [111] of the piezoresistive thin film is perpendicular to the substrate when the piezoresistive thin film is germanium or doped germanium.

### BRIEF DESCRIPTION OF THE DRAWINGS

In order to make the above and other objects, features, advantages, and embodiments of the invention more comprehensible, the description of the attached drawings is as follows:

FIG. 1A is a diagram showing an explosive view of a bending sensing device according to an embodiment of this invention.

FIG. 1B is a diagram showing a top view of the assembled bending sensing device in FIG. 1A.

FIG. 2A is a schematic diagram of the lattice structure of mica.

FIG. 2B is a schematic diagram of the lattice structure of ZnO.

FIG. 2C is an XRD pattern of the substrate (mica) of the bending sensing device.

FIG. 2D is an XRD pattern of the piezoresistive thin film (ZnO) disposed on the substrate (mica) in the bending sensing device.

FIG. 3A is a schematic structural diagram showing a bending sensing device bent in a flex-out direction.

FIG. 3B is a schematic structural diagram showing a bending sensing device bent in a flex-in direction.

FIG. 4A is a schematic diagram of measuring the resistance of multiple sections of the bending sensing device.

FIG. 4B is a schematic diagram of measuring the resistance of multiple axes of the bending sensing device.

FIG. 5 is a diagram showing the relationship between the incident light wavelength and the transmittance of ZnO according to an embodiment of the invention.

FIG. 6A is a diagram showing the relationship between the thickness and flex-out resistance change rate of a piezoresistive thin film of ZnO in a bending sensing device according to some embodiments of the invention.

FIG. 6B is a diagram showing the relationship between the thickness and flex-in resistance change rate of a piezoresistive thin film of ZnO according to some embodiments of the invention.

FIG. 7 is a diagram showing a relationship between the thickness of the substrate and the flex-in resistance change rate of a ZnO piezoresistive thin film according to some embodiments of the invention.

FIG. 8 is a diagram showing the bending fatigue test results of a bending sensing device with a ZnO piezoresistive thin film according to some embodiments of the invention.

FIG. 9 is a diagram showing a bending cycle test results of a bending sensing device with a ZnO piezoresistive thin film according to some embodiments of the invention.

FIG. 10 is an XRD pattern of a piezoresistive thin film (Ge) disposed on a substrate (mica) in a bending sensing device according to some embodiments of the invention.

FIG. 11 is a diagram showing a relationship between the thickness of the substrate and the resistance change rate of Ge piezoresistive thin films in bending sensing device according to some embodiments of the invention.

### DETAILED DESCRIPTION

In view of the above problems, a bending sensing device is provided. An inorganic piezoresistive layer is used as a main part of the bending sensing device, conductive electrodes are formed on the main part and electrically connected to a resistance measurement device for measuring the resistance variation of the inorganic piezoresistive layer while bending. After the value of the resistance variation is measured, the corresponding curvature radius of the inorganic piezoresistive layer is obtained according to the corresponding relationship between the curvature radius and the resistance variation.

Since an inorganic piezoresistive layer is used, the bending sensing device can improve and overcome the disadvantages of the prior art (such as using organic materials as the main part), including poor accuracy, not resistant to high temperature, acid and alkali, complicated device structure, and dark or opaque appearance.

In addition, through the characteristic of the inorganic piezoresistive layer and the structural features of the bending sensing device, the bending sensing device can even unexpectedly be used in multiple sections and multiple axes at the same time to identify the degree of curvature (curvature radius) at the corresponding measurement section. Therefore, the bending sensing device can successfully overcome the shortcomings of the conventional whole bending sensing device (i.e., only a single curved or uniaxial measurement section can be measured at one time) to extend and broaden the application and development in related fields.

In order to explain the embodiments of the invention more clearly, the invention provides embodiments, which are described in detail as below.

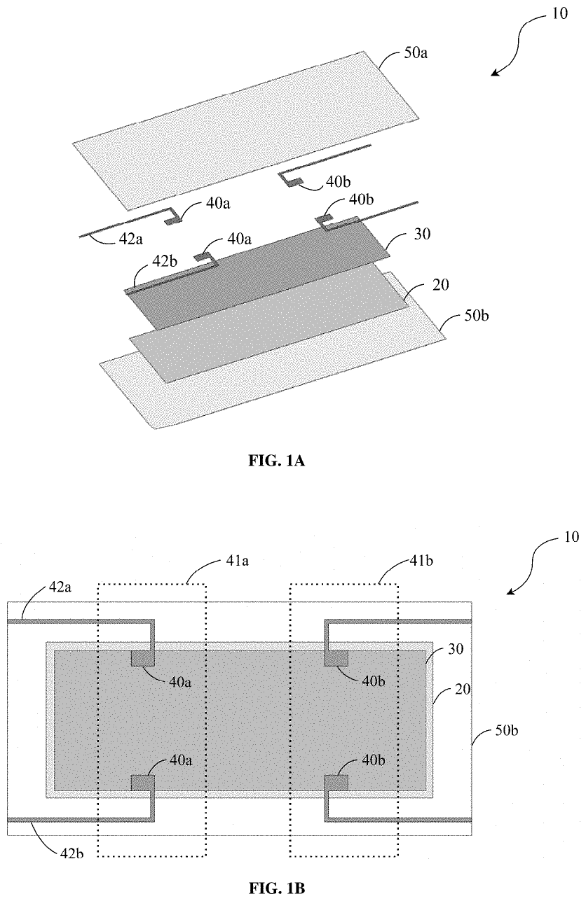

FIG. 1A is a diagram showing an explosive view of a bending sensing device according to an embodiment of this invention, and FIG. 1B is a diagram showing a top view of the assembled bending sensing device in FIG. 1A. In FIGS. 1A and 1B, a bending sensing device 10 comprises a substrate 20, a piezoresistive thin film 30, a first electrode 40a, and a second electrode 40b.

The substrate 20 is a two-dimensional (2D) structure that is bendable or flexible, and a material of the substrate 20 is mica. Mica can be produced by top-down exfoliation or bottom-up synthesis to produce a 2D layered structure with a single layer or multiple layers. This 2D layered mica has bendability or flexibility, high operation temperature tolerance up to 1000° C., good thermal conductivity, and high light transmittance in the visible light wavelength range and thus transparent appearance. Because of the above characteristics of mica, mica is an excellent material suitable for use as a substrate for carrying and is thus selected as the material of the substrate 20.

According to some embodiments, the thickness of the substrate 20 is better not to be greater than 100 μm due to the structure and application of the substrate 20 in this bending sensing device. If the thickness of the substrate 20 is too thin, the mechanical strength of the substrate 20 will be insufficient. However, if the thickness of the substrate 20 is too thick, the substrate 20 is likely to be broken when the substrate 20 is bent or deformed.

The piezoresistive thin film 30 is heteroepitaxially grown on the substrate 20, and the growth method of the piezoresistive thin film 30 comprises deposition or plating, for example. For the heteroepitaxial crystal, owing to the mica selected for the substrate 20, is newly peeled, the surface of the mica is a flat and wide platform without active dangling bonds. Therefore, a weak force (such as a van der Waals force) and only a very minor deformation caused by lattice mismatching is formed between the substrate 20 and the epitaxial layer of the piezoresistive thin film 30. The lattice mismatching is so small that a nearly perfectly matched epitaxy is formed, so the very minor imperfect matching can be almost ignored. The method of forming epitaxy by the van der Waals force is often called van der Waals epitaxy (vdWE).

The material of the piezoresistive thin film 30 is an inorganic piezoresistive material comprising zinc oxide (ZnO), doped ZnO (such as aluminum-doped ZnO, AZO), germanium (Ge), doped Ge, or any combinations thereof. The selection of the inorganic material is determined by the resistance, the energy band gap, and the lattice structure of the inorganic piezoresistive material. Generally, those with large resistance, large band gap, lattice structure that can nearly perfectly match the crystal lattice of the substrate 20 will be selected as candidate materials. In one embodiment, ZnO is selected as the material of the piezoresistive thin film 30. The dopant of the doped ZnO comprises Al(III), Ga(III), In(III), or any combinations thereof.

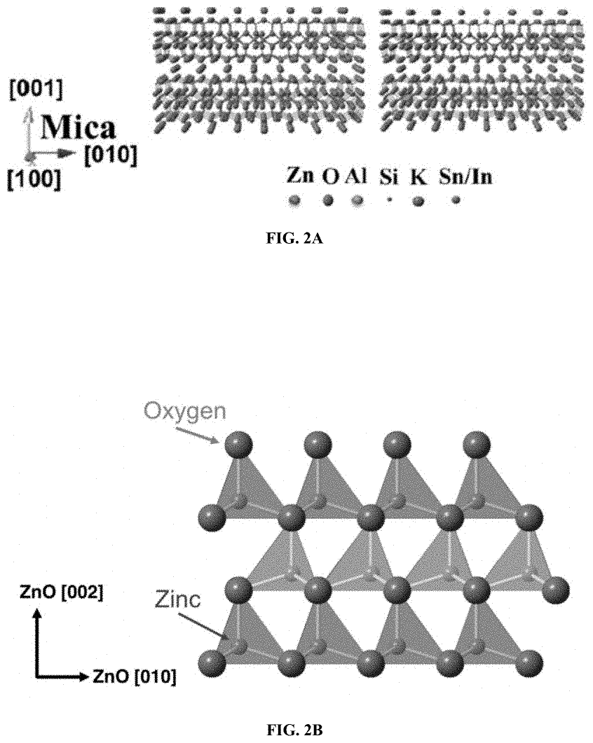

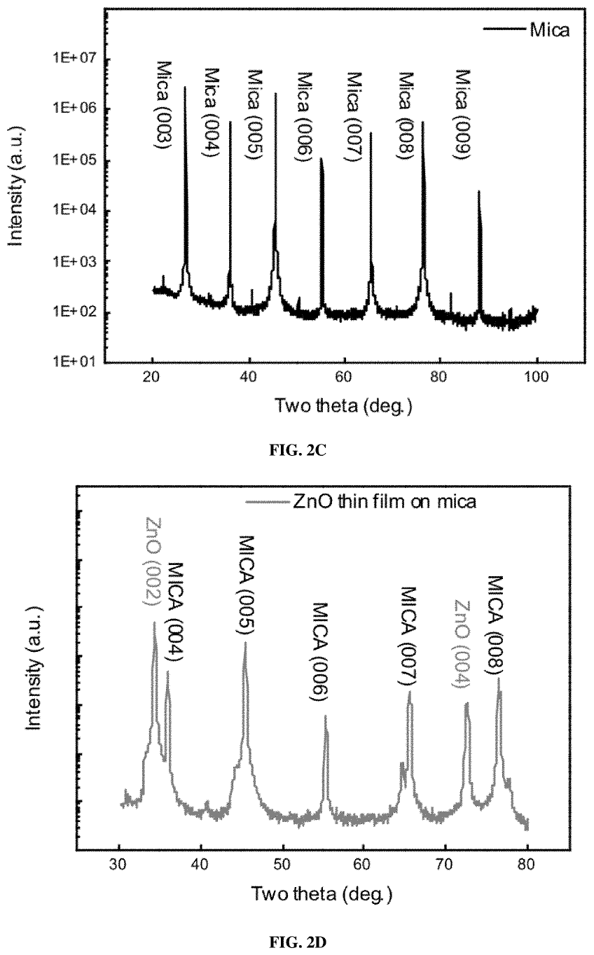

FIG. 2A is a schematic diagram of the lattice structure of mica, which is a material of the substrate 20 above. FIG. 2B is a schematic diagram of the lattice structure of ZnO, which is a material of the piezoresistive thin film 30. In the bending sensing device, both lattice arrangement direction of the mica of the substrate 20 and the ZnO of the piezoresistive thin film 30 are [010] by Miller index. FIG. 2C is an XRD pattern of the substrate (mica) of the bending sensing device, and FIG. 2D is an XRD pattern of the piezoresistive thin film (ZnO) disposed on the substrate (mica) in the bending sensing device. Through FIG. 2C, the peak appeared at 2θ angle of 36° can be clearly identified as the characteristic peak (004) of the mica substrate 20. Further through FIG. 2D, the peak appeared at 2θ angles of 34° can be clearly identified as the characteristic peak (002) of the mica substrate 20. Therefore, it can be inferred that the lattice arrangement directions of the substrate 20 and the piezoresistive thin film 30 need to be Miller index [001] and [002] in order to epitaxially match. In one embodiment, the ZnO material of the piezoresistive thin film 30 is preferably disposed on the substrate 20 in such a manner that the direction of the Miller index [001] of the piezoresistive thin film 30 is perpendicular to the substrate 20.

Still in FIG. 1B, the first electrode 40a and the second electrode 40b are respectively disposed on a first measurement section 41a and a second measurement section 41b of the piezoresistive thin film 30, and the first electrode 40a and the second electrode 40b are electrically connected to two ends of the first measurement section 41a and the second measurement section 41b, respectively. Furthermore, taking the first electrode 40a as an example, the pair of the first electrodes 40a respectively extend a first terminal 42a and a second terminal 42b towards the outer edge direction of the substrate 20. The material of the first electrodes 40a and the second electrodes 40b comprises a transparent conductive oxide, such as indium tin oxide (ITO) and doped zinc oxide (ZnO). In addition, the dopant in the doped ZnO comprises Al(III), Ga(III), In(III), or any combinations thereof.

Still in FIG. 1B, through the electrical connection method, and applying a voltage to the bending sensing device 10, the corresponding resistance values of the first measurement section 41a and the second measurement section 41b can be then obtained according to Ohm's Law. However, since the piezoresistive thin film 30 of the bending sensing device 10 is a piezoresistive material. When the piezoresistive material is subjected to mechanical stress (such as bending), the Ohm's Law can be used to calculate the varied value of the resistance after bending. A resistance change relationship diagram can be obtained by plotting the resistance values obtained under different bending degrees caused by different stress levels versus stress levels. Then, a resistance measuring device (not shown in the figure) can be used to measure the resistance values of the first measurement section 41a and the second measurement section 41b, and the corresponding stress level (reflected by the bending degree) of the first measurement section 41a and the second measurement section 41b can be obtained by referring to the resistance change relationship diagram.

In FIG. 1A, the bending sensing device 10 further comprises a first protection layer 50a and a second protection layer 50b respectively disposed on two sides of the bending sensing device 10. Besides, the material of the first protection layer 50a and the second protection layer 50b has properties of transparent, bendable, and flexible, such as polyethylene terephthalate (PET). The first protection layer 50a and the second protection layer 50b are closely adhered to the bending sensing device 10, and have functions of delaying the oxidation or aging of the internal components of the bending sensing device 10 to protect the internal components and extend the service life thereof.

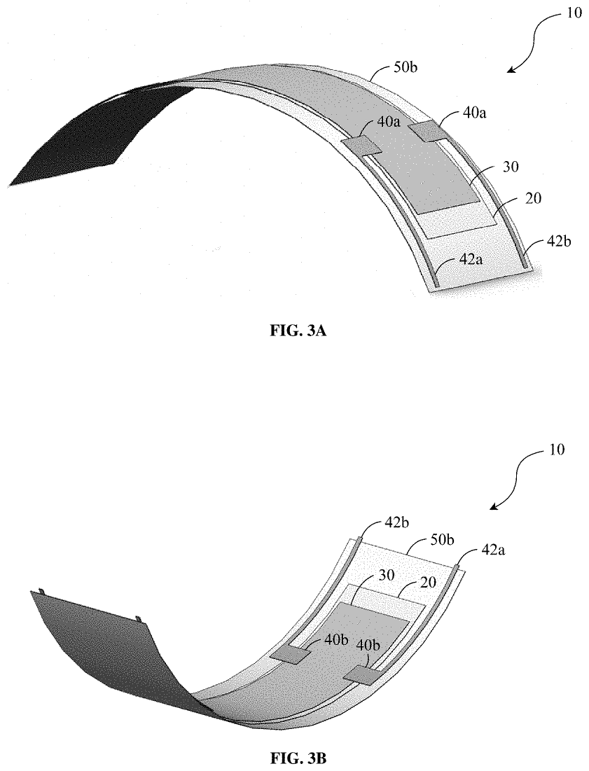

FIG. 3A is a schematic structural diagram showing a bending sensing device bent in a flex-out direction. In FIG. 3A, the outer layer of the bending sensing device 10 is defined herein as a side having the first electrode 40a and the second electrode 40b, and the inner layer is a side having the substrate 20. “Flex-out” means that the piezoresistive thin film 30 will be located on an outer side after the substrate 20 is bent. FIG. 3B is a schematic structural diagram showing a bending sensing device bent in a flex-in direction. In FIG. 3B, “flex-in” means that the piezoresistive thin film 30 will be located on an inner side after the substrate 20 is bent.

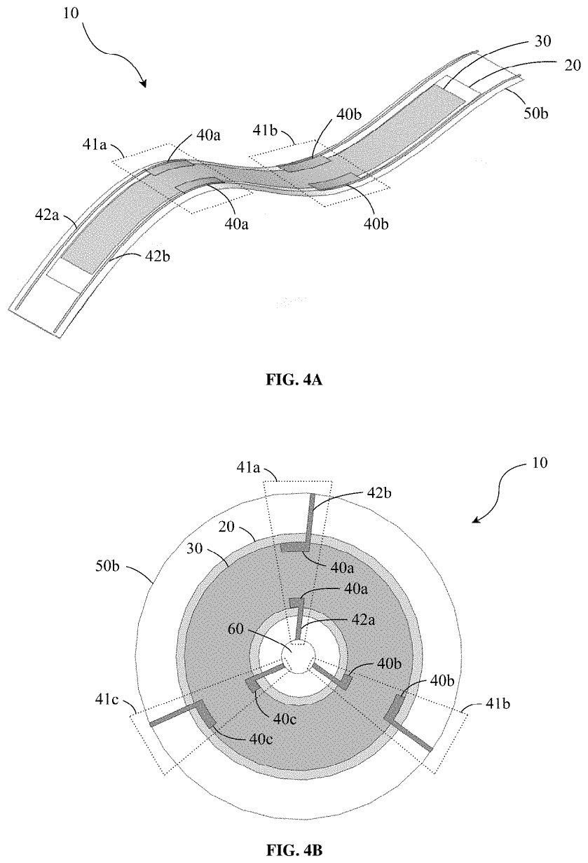

FIG. 4A is a schematic diagram of measuring the resistance of multiple sections of the bending sensing device. In FIG. 4A, a bending sensing device having two electrode pairs (i.e. a first pair of the first electrodes 40a and a second pair of the second electrodes 40b) are shown as an example. However, the number of electrode pairs is not limited here. Any number of electrode pairs may be used on a bending sensing device.

Still in FIG. 4A, taking the first electrode 40a as an example, the first terminal 42a and the second terminal 42b of the first electrode 40a are respectively and correspondingly disposed within the section of the first measurement section 41a, which is selectively measured, on the piezoresistive thin film 30. The first measurement section 41a is a section of the piezoresistive thin film 30 that can be bent or flexed during operation, so the resistance values of the first measurement section 41a in the bending sensing device 10 can be respectively obtained through the resistance measuring device when the bending sensing device 10 is flat or bent.

Still in FIG. 4A, the resistance value measured when the first measurement section 41a is flat is used as a reference value and is compared with the measured resistance values measured when the first measurement section 41a is not flat or bent. As the measured resistance value deviates from the reference resistant value, it can be known that the bending degree of the first measurement section 41a is greater. Further, according to the relationship between the curvature radius and the resistance value obtained from the resistance change relationship diagram, the curvature radius and the bending degree corresponding to each resistance value can be obtained.

Still in FIG. 4A, if the electrode pairs (that is, both the first electrodes 40a and the second electrodes 40b) of the first measurement section 41a and the second measurement section 41b can be used at the same time, the resistance values of multiple sections can be then independently detected. In this embodiment, the obtained resistance values are those of the two measurement sections. That is, the bending sensing device 10 is capable of simultaneously sensing the bending degree of selected multiple sections (i.e., multiple measurement sections).

FIG. 4B is a schematic diagram of measuring the resistance of multiple axes of the bending sensing device. As shown in the bending sensing device 10 in FIG. 4B, it is further designed into a hollow structure, such as with a hollow portion 60, without mutually contacting. The hollow structure can be an open or closed circular connection, or various geometric shapes, comprising arcs or sectors with various angles, irregular curves or twists, such as the structure of donut shape (as shown in FIG. 4B) or square hollow shape, and equivalents thereof.

As shown in the bending sensing device 10 in FIG. 4B, three electrode pairs (that is, first electrodes 40a, second electrodes 40b, and third electrodes 40c) were further taken as an illustrative embodiment. The three electrode pairs were evenly disposed on the donut-shaped bending sensing device 10. The average interval angle between the three electrode pairs is 120°, and they are not connected to each other at the hollow portion 60. It is not limited to the interval angle above. Any interval angles that can effectively separate the three electrode pairs may be used here.

Still in FIG. 4B, through the resistance measurement method above, the different resistance values of the three electrode pairs (respectively disposed on the first measurement section 41a, the second measurement section 41b and the third measurement section 41c) can be respectively obtained. The actual curvature radii thereof could be further respectively obtained through the relationship between the bending degrees and the resistance values.

If the directions and angles of the three pairs are further expressed by linear equations, for example, the first electrodes 40a may be expressed as x=0, the second electrodes 40b may be expressed as x+\sqrt{3}y=0, and the third electrodes 40c may be expressed as x−\sqrt{3}y=0. That is, the first electrodes 40a, the second electrodes 40b, and the third electrodes 40c were respectively disposed on the three-axis measurement sections represented by different linear equations. Therefore, the resistance values of multiple axes corresponding to the first measurement section 41a, the second measurement section 41b, and the three measurement sections 41c can be simultaneously measured by respectively making electrical connection to the first electrodes 40a, the second electrodes 40b, and the third electrodes 40c. Accordingly, the bending sensing device 10 was capable of sensing the bending degree of multiple axes simultaneously.

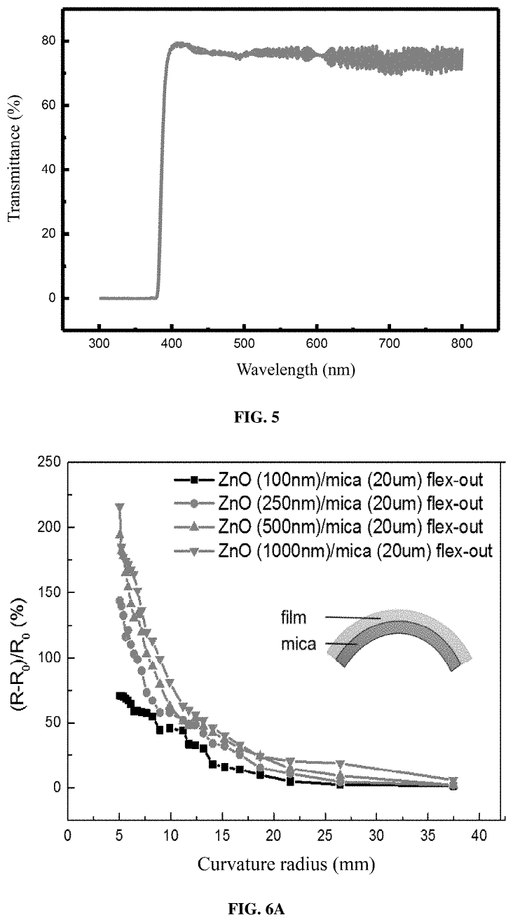

FIG. 5 is a diagram showing the relationship between the incident light wavelength and the transmittance of ZnO according to an embodiment of the invention. The substrate 20 was a mica substrate having a thickness of 20 μm, the piezoresistive thin film 30 was a ZnO thin film having a thickness of 1000 nm, and the first electrodes 40a were made of ITO. Through a UV/Vis spectrophotometer, the corresponding relationship between the transmittance and incident light wavelength was obtained as shown in FIG. 5.

In FIG. 5, the horizontal axis represents the incident light wavelength (nm) and the vertical axis represents the transmittance (%). In FIG. 5, it showed that the transmittance was at least above 70%, and even as high as 80% when the wavelength was in the range of 390-700 nm (visible light). Owing to the excellent transmittance, the bending sensing device 10 might be translucent or even transparent to the naked eye and thus may be further applied to many other industries, such as rehabilitation monitoring systems, virtual reality (VR) motion simulators, robot joint controllers, gas flow rate sensors, or robotic arm monitoring, etc.

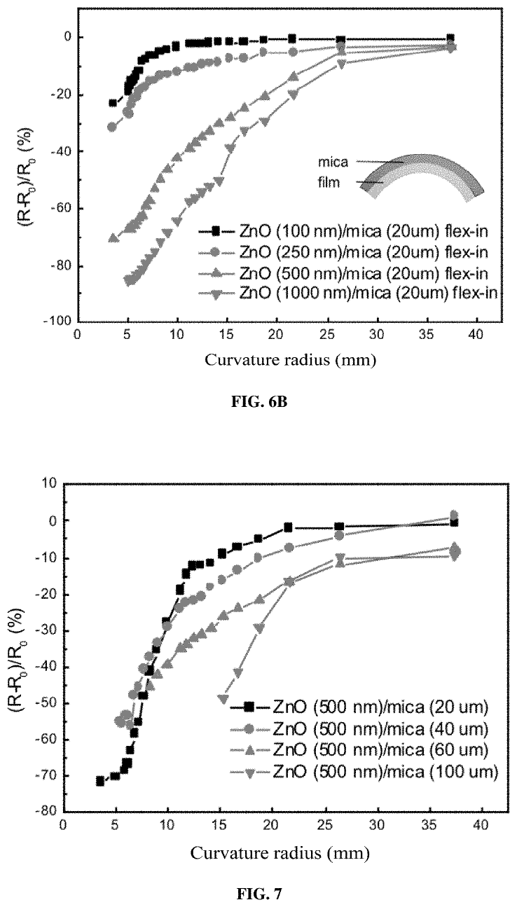

FIG. 6A is a diagram showing the relationship between the thickness and flex-out resistance change rate of a piezoresistive thin film of ZnO in a bending sensing device according to some embodiments of the invention. The substrate 20 was made of mica, the piezoresistive thin film 30 was made of ZnO, and the first electrodes 40a and the second electrodes 40b were made of ITO. The thickness of the substrate 20 was fixed to 20 μm, and the thicknesses of the piezoresistive thin film 30 were 100, 250, 500, and 1000 nm respectively. Each of the bending sensing devices 10 was bent in the flex-out manner with various bending degrees having various curvature radius. In FIG. 6A, it showed that the thicker the piezoresistive thin film 30, the more significant the resistance change rate of the piezoresistive thin film 30 when the curvature radii of the first measurement section 41a and the second measurement section 41b were the same. The curvature radii of the first measurement sections 41a and the second measurement sections 41 were at least (not less than) 5 mm respectively for each of the bending sensing devices 10.

FIG. 6B is a diagram showing the relationship between the thickness and flex-in resistance change rate of a piezoresistive thin film of ZnO according to some embodiments of the invention. The bending sensing device 10 was the same as above, wherein the thickness of the substrate 20 was fixed to 20 μm, and the thicknesses of the piezoresistive thin film 30 were 100, 250, 500, and 1000 nm respectively. Each of the bending sensing devices 10 was bent in the flex-in manner with various bending degrees having various curvature radius. In FIG. 6B, it showed that the thicker the piezoresistive thin film 30, the more significant the resistance change rate of the piezoresistive thin film 30 when the curvature radii of the first measurement section 41a and the second measurement section 41b were the same. The curvature radii of the first measurement sections 41a and the second measurement sections 41 were at least (not less than) 3.5 mm respectively for each of the bending sensing devices 10.

FIG. 7 is a diagram showing a relationship between the thickness of the substrate and the flex-in resistance change rate of a ZnO piezoresistive thin film according to some embodiments of the invention. The bending sensing devices 10 were the same as above, wherein the thickness of the piezoresistive thin films 30 was fixed to 500 nm, and the thicknesses of the substrates 20 were 20, 40, 60, and 100 μm respectively. Each of the bending sensing devices 10 was bent in the flex-in manner with various bending degrees having various curvature radius. According to the tendency shown in FIG. 7, it showed that the resistance change rate of the ZnO piezoresistive thin film was affected by the curvature radii of the first measurement section 41a and the second measurement section 41b. Furthermore, the influence of the 20 μm thick substrate 20 on the resistance change rate of the ZnO piezoresistive thin film was more significant than of the 100 μm thick substrate 20. The curvature radii of the first measurement sections 41a and the second measurement sections 41b of the bending sensing devices 10 were at least (not less than) 3.5 mm respectively.

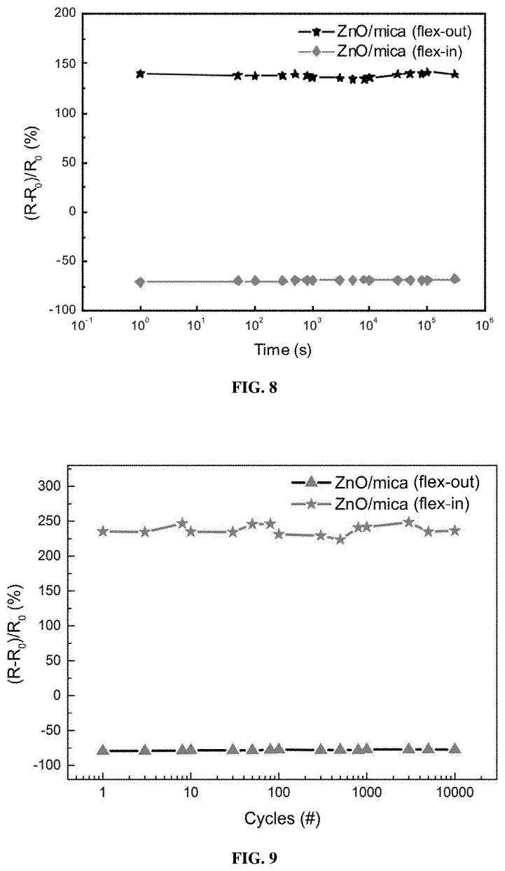

FIG. 8 is a diagram showing the bending fatigue test results of a bending sensing device with a ZnO piezoresistive thin film according to some embodiments of the invention. The bending sensing devices 10 were the same as above. The thickness of the piezoresistive thin film 30 was 500 nm, the thickness of the substrates 20 was 20 μm. The bending fatigue test was performed by maintaining the bending sensing device in a flex-in or flex-out status with a curvature radius of 5 mm for a period of time.

In FIG. 8, it showed that whatever the bending direction of the bending sensing device 10 was, the duration could be at least 10⁵ seconds, far more than 24 hours (equal to 86,400 seconds). Therefore, the stability of the bending sensing device 10 shows a better performance than a conventional bending sensing device which duration is merely about 10³ seconds due to the deformation of the organic materials.

FIG. 9 is a diagram showing a bending cycle test results of a bending sensing device with a ZnO piezoresistive thin film according to some embodiments of the invention. The bending sensing device 10 was the same as above. The thickness of the piezoresistive thin film 30 was 500 nm, the thickness of the substrate 20 was 20 μm. The bending cycle test was performed by repeatedly bending the bending sensing device 10 in a flex-in or flex-out manner with a curvature radius of 5 mm for many times.

In FIG. 9, it showed that whatever the bending direction of the bending sensing device 10 was, the bending cycle could be at least 10,000 counts. Therefore, the durability of the bending sensing device 10 shows a better performance than a conventional bending sensing device which can only endure the cycle test hundreds or thousands times due to their inherent mechanical properties of the polymer and metal materials.

In another embodiment of the invention, the material of the piezoresistive thin film 30 was Ge while the materials of the rest components of the bending sensing device 10 were the same as above.

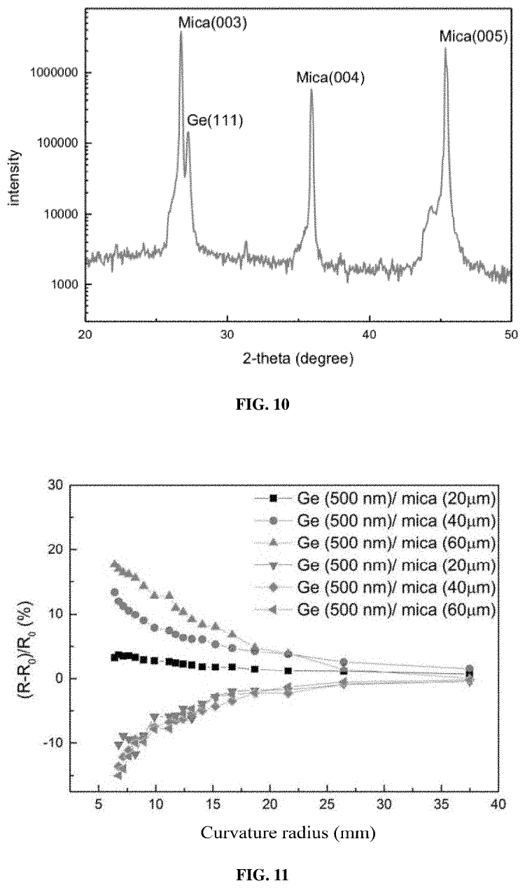

FIG. 10 is an XRD pattern of a piezoresistive thin film (Ge) disposed on a substrate (mica) in a bending sensing device according to some embodiments of the invention. In FIG. 10, the peaks appeared at 2θ angles of 27°, 36°, and 45° can be clearly identified as the characteristic peaks (003), (004), and (005) of the mica substrate 20 by referring to the XRD pattern of mica shown in FIG. 2C. As for the peak appeared at 2θ angle of 28°, it was identified as the characteristic peak (111) of Ge thin film. Therefore, it can be known that the lattices of both the mica substrate and the Ge thin film disposed on the mica substrate are aligned on the direction of the Miller index (111). That is, the Ge piezoresistive thin film was preferably disposed on the substrate 20 in such a manner that the direction of the Miller index (111) of the piezoresistive thin film 30 was perpendicular to the surface of the substrate 20.

FIG. 11 is a diagram showing a relationship between the thickness of the substrate and the resistance change rate of Ge piezoresistive thin films in bending sensing device according to some embodiments of the invention. The bending sensing devices 10 were the same as above. The thickness of the Ge piezoresistive thin film was 500 nm, and the thicknesses of the substrate 20 of mica were 20, 40, or 60 μm respectively. Each of the bending sensing devices 10 was bent in the flex-in or flex-out manner with various bending degrees having various curvature radius. When the resistance measurement method was applied, each of the resistance values was obtained and depicted as in FIG. 11. In FIG. 11, it showed that the resistance change rate of the Ge piezoresistive thin films was affected by the curvature radii of the first measurement section 41a and the second measurement section 41b. Furthermore, the resistance change rate of the Ge piezoresistive thin films was increased as the thickness of the mica substrate 20 was increased. The curvature radii of the first measurement sections 41a and the second measurement sections 41b of the bending sensing devices 10 were at least (not less than) 5 mm respectively.

The above embodiments of the invention successfully provide bending sensing devices, each comprising a substrate, a piezoresistive thin film, and a pair of electrodes. The piezoresistive thin film has a significant difference in resistance value due to the piezoresistive effect when it is subjected to a bending force. Followed by electrically connecting the electrodes to a resistance measuring device, the corresponding resistance values may be obtained. Through the transformation of the data, the bending degree or the stress degree could be further obtained. In addition, due to material properties of each component in the bending sensing device, the device thus has inherent properties such as transparency, multi-section and multi-axis sensing. Therefore, the bending sensing devices not only overcome the technical obstacles and disadvantages encountered in the prior art, but also provided a convenient, forward-looking and integrated bending sensing device for the related field.

The invention was only disclosed some embodiments herein. However, anyone familiar with the technical field or skilled in the art should understand that the embodiments are only used to describe the invention, and not intended to limit the scope of patent rights claimed by the invention. Any changes or substitutions that are equivalent to the embodiments should be construed as being included within the spirit or scope of the invention. Therefore, the scope of protection of the invention shall be defined by the claims of patent application described below.

What is claimed is:

1. An bending sensing device, comprising:
a substrate having a flexible two-dimensional structure, wherein a material of the substrate is mica;
a piezoresistive thin film disposed on the substrate and having at least one measurement section, wherein a material of the piezoresistive thin film is an inorganic material comprising zinc oxide, doped zinc oxide, germanium, doped germanium, or any combinations thereof; and
at least one pair of electrodes respectively disposed on two terminals of the at least one measurement section of the piezoresistive thin film.

2. The bending sensing device of claim 1, wherein these electrodes are made from a transparent conductive oxide comprising indium tin oxide or doped zinc oxide.

3. The bending sensing device of claim 1, further comprising a plurality of protection layers covering exposed surfaces of the substrate, the piezoresistive thin film and the electrodes, wherein a material of these protection layers comprises polyethylene terephthalate (PET).

4. The bending sensing device of claim 1, wherein the at least one measurement section is disposed on at least one axial direction of the bending sensing device.

5. The bending sensing device of claim 4, wherein the at least one measurement section is curved and has a curvature radius not less than 3.5 mm.

6. The bending sensing device of claim 1, further comprising a plurality of resistance measurement devices respectively electrically connected to the electrodes to measure a plurality of resistance values.

7. The bending sensing device of claim 1, wherein the substrate has a thickness of not greater than 100 μm.

8. The bending sensing device of claim 1, wherein the piezoresistive thin film has a thickness of 100-10000 nm.

9. The bending sensing device of claim 1, wherein the piezoresistive thin film is disposed on the substrate in such a manner that the direction of the Miller index [001] of the piezoresistive thin film is perpendicular to the substrate when the piezoresistive thin film is zinc oxide or doped zinc oxide.

10. The bending sensing device of claim 1, wherein the piezoresistive thin film is disposed on the substrate in such a manner that the direction of the Miller index [111] of the piezoresistive thin film is perpendicular to the substrate when the piezoresistive thin film is germanium or doped germanium.
